(19) United States
(12) Patent Application Publication
(10) Pub. No.: US 2012/0285371 A1
(43) Pub. Date: Nov. 15, 2012

(54) METHOD FOR MAKING FLAT SUBSTRATE FROM INCREMENTAL-WIDTH NANORODS WITH PARTIAL COATING

(75) Inventors: Chong Ming Lee, Taipei (TW); Andrew Eng Jia Lee, Taipei (TW)

(73) Assignee: Nanocrystal Asia Inc., Taipei (TW)

(21) Appl. No.: 13/268,093

(22) Filed: Oct. 7, 2011

Related U.S. Application Data
(60) Provisional application No. 61/484,900, filed on May 11, 2011.

(51) Int. Cl. C30B 25/02; C30B 25/18

(52) U.S. Cl. 117/104

(57) ABSTRACT

A method for making a flat substrate from incremental-width nanorods includes the steps of: providing a base layer, performing a lateral crystal growth process for a plurality of times, and forming a substrate. The base layer has a plurality of nanorods. Each time the lateral crystal growth process is performed, an additive reagent is added at a different concentration to enable lateral crystal growth and thereby increase the width of each nanorod incrementally. The incremental-width nanorods eventually bond with each other to form a substrate. The substrate may go through an annealing process so as to become a flat substrate.

### PRIORITY

This application claims the priority date of May 11, 2011, the filing date of the corresponding U.S. Provisional Application No. 61/484,900.

### TECHNICAL FIELD

The present invention relates to a method for making a flat substrate from incremental-width nanorods and, more particularly, to a method for incrementally increasing the widths of nanorods and thereby making a flat substrate on which a gallium nitride layer can be subsequently formed.

### DESCRIPTION OF RELATED ART

Sapphire—which features exceptional hardness, remarkable resistance to high temperature and chemical corrosion, and low conductivity for both heat and electricity—is commonly used as a base layer for growing gallium nitride layers. However, due to the huge difference of thermal expansion coefficients, as well as a mismatch of lattice constants, between the sapphire base layer and the gallium nitride layer, the gallium nitride layer growing on the surface of the sapphire base layer tends to crack under high stress during the process in which both layers are first heated to a high temperature and then cooled down.

Therefore, in order to grow a gallium nitride layer on a sapphire base layer, it is conventionally required to grow a buffer layer on the sapphire base layer in advance, so as for the buffer layer to reduce stress-induced defects and thereby lower the defect density in the gallium nitride layer. The buffer layer is typically an oxide or silicon carbon nitride (SiCN) layer grown between the sapphire base layer and the gallium nitride layer in order to eliminate the mismatch of lattice constants therebetween.

Nevertheless, when the buffer layer is formed of silicon carbon nitride or amorphous nitride, surface defects are likely to occur on the buffer layer itself such that the gallium nitride layer grown on the buffer layer is also prone to be defective. Hence, the buffer layer, though capable of reducing stress-induced cracks, is ineffective in lowering the defect density in the gallium nitride layer. In consideration of the above, it is a pressing issue in the related industry to prevent gallium nitride layers from damage or cracks attributable to stresses in the manufacturing process.

### SUMMARY OF THE INVENTION

It is an objective of the present invention to provide a method for making a flat substrate from incremental-width nanorods, wherein a crystal growth process is performed on a base layer with nanorods for multiple times. Each time the crystal growth process is performed, an additive reagent is added at a different concentration to enable lateral crystal growth and thereby increase the widths of the nanorods incrementally until a substrate is formed. The substrate may be further annealed to reduce its defect density and form a seed layer.

To achieve the above objective, the present invention provides a method for making a flat substrate from incremental-width nanorods, wherein the method includes the following steps. To begin with, a base layer having a plurality of nanorods is provided. Then, a lateral crystal growth process is performed for a plurality of times to enable lateral crystal growth of the nanorods, wherein each time the lateral crystal growth process is performed, an additive reagent is added at a different concentration. After the lateral crystal growth process is performed multiple times to widen each nanorod incrementally, the incremental-width nanorods bond with each other and form a substrate.

Implementation of the present invention at least produces the following advantageous effects:

1. The incremental-width nanorods can be used in place of the conventional buffer layer to prevent the base layer from damage or cracks attributable to stresses in the manufacturing process.

2. The incremental-width nanorods can be easily severed along the transverse direction to prevent the base layer from being damaged by a crystal layer growing thereon that keeps thickening.

3. The seed layer, which has few surface defects, can significantly increase the upper limit of the thickness of a crystal layer growing from the seed layer and lower the defect density in the crystal.

The detailed features and advantages of the present invention will be described in detail with reference to the preferred embodiments so as to enable persons skilled in the art to gain insight into the technical disclosure of the present invention, implement the present invention accordingly, and readily understand the objectives and advantages of the present invention by perusal of the contents disclosed in the specification, the claims, and the accompanying drawings.

### BRIEF DESCRIPTION OF THE DRAWINGS

FIG. 1 is the flowchart of a method according to an embodiment of the present invention for making a flat substrate from incremental-width nanorods;

FIG. 2 schematically shows a base layer having a plurality of nanorods according to an embodiment of the present invention;

FIG. 3 schematically shows how the nanorods grow in width according to an embodiment of the present invention;

FIG. 4 schematically shows how the nanorods bond with each other after their widths are increased multiple times according to an embodiment of the present invention;

FIG. 5 schematically shows a seed layer transformed according to an embodiment of the present invention; and

FIG. 6 schematically shows a gallium nitride layer grown on the seed layer depicted in FIG. 5.

### DETAILED DESCRIPTION OF THE INVENTION

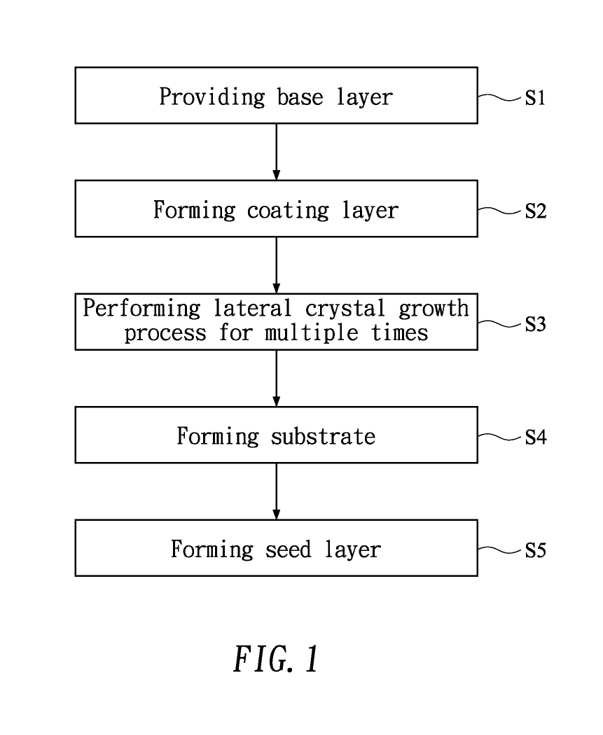

Please refer to FIG. 1 for an embodiment of the present invention, in which a method for making a flat substrate from incremental-width nanorods includes the steps of: providing a base layer (S10), performing a lateral crystal growth process for a plurality of times (S20), forming a substrate (S30), and forming a seed layer (S40).

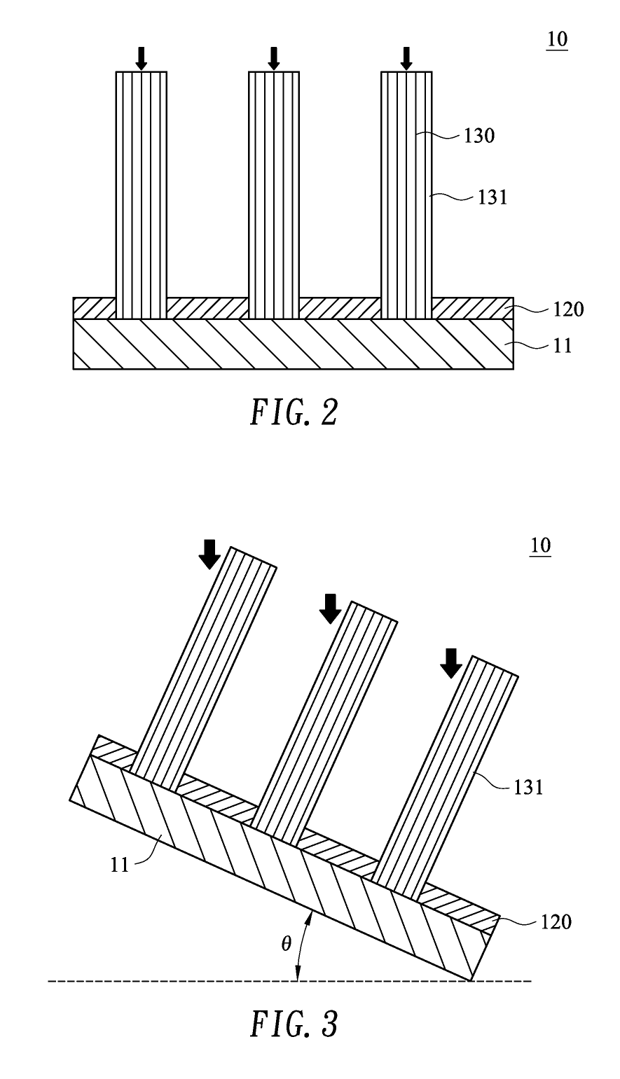

Providing a base layer (S10): As shown in FIG. 2, the present embodiment begins by providing a base layer 10 having a plurality of nanorods 130. The process for preparing such a base layer 10 is well know in the art and hence is not described herein. The base layer 10 includes a base board 11, which can be made of monocrystalline silicon, silicon carbide, sapphire, or lithium aluminate, for example. In order to form nanowires 131 on the base layer 10, one surface of the base board 11 is covered with an insulating layer 12, such as a silicon nitride (SiN_{X}) or silicon oxide (SiO₂) layer. Then, the silicon nitride or silicon oxide layer is formed with a plurality of openings (not shown) by an etching or nano-imprint technique. After that, the nanowires 131 are grown from the openings. The multiple nanowires 131 in each opening gather together to form one nanorod 130.

With the insulating layer 12 formed with the plural openings, the nanorods 130 are distributed over the base layer 10 in a spaced manner. The nanorods 130 are typically made of a semiconductor material, some common examples of which are III-V or II-VI compound semiconductors. In this embodiment, the nanorods 130 are made of gallium nitride.

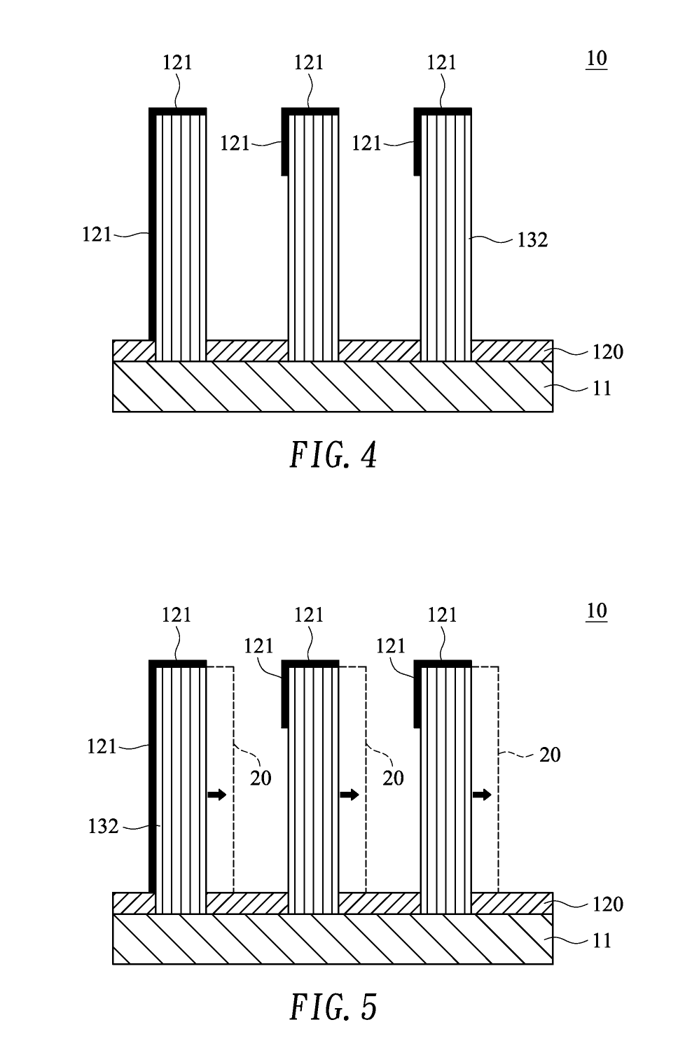

Performing a lateral crystal growth process for a plurality of times (S20): Referring to FIG. 3, a lateral crystal growth process is performed on the base layer 10 for multiple times. In the present embodiment, metal-organic chemical vapor deposition (MOCVD) is carried out to enable lateral crystal growth of the nanorods 130 and formation of extra-width nanorods 20 (i.e., the additionally grown portions of the nanorods 130). In order to form a substrate 30 stably, the widths of the nanorods 130 must be increased incrementally through multiple lateral crystal growths.

With a view to facilitating lateral crystal growth of the nanorods 130, the metal-organic chemical vapor deposition process entails the use of a trimethylgallium gas, an ammonia gas, and an additive reagent, wherein the additive reagent is added successively at different concentrations. More specifically, the base layer 10 is put in a reactor chamber into which the trimethylgallium gas is introduced, followed by the ammonia gas. During the aforesaid process, the additive reagent, such as a nitride-based compound or hydrogen, is also added to enable gradual increase of the nanorods 130 in width.

Each time the lateral crystal growth process is performed on the nanorods 130, the additive reagent is added at a different concentration so as to control the growth widths of the nanorods 130 by varying the concentration of the additive reagent. The various concentrations of the additive reagent produce different crystal growth conditions and hence different lateral growth widths of the nanowires 131. Thus, by performing the lateral crystal process successively with a specific concentration gradient of the additive reagent, the widths of the nanorods 130 are steadily increased by increments.

For example, the additive reagent is first added at a C1 percent concentration to enable transverse growth of the nanowires 131. Since an additive reagent of a specific concentration can only cause the extra-width nanorods 20 to grow laterally to specific widths and no more than the specific widths, the additive reagent is subsequently added at a C2 percent concentration so as for the nanowires 131 to grow laterally again and for the extra-width nanorods 20 to further increase in width.

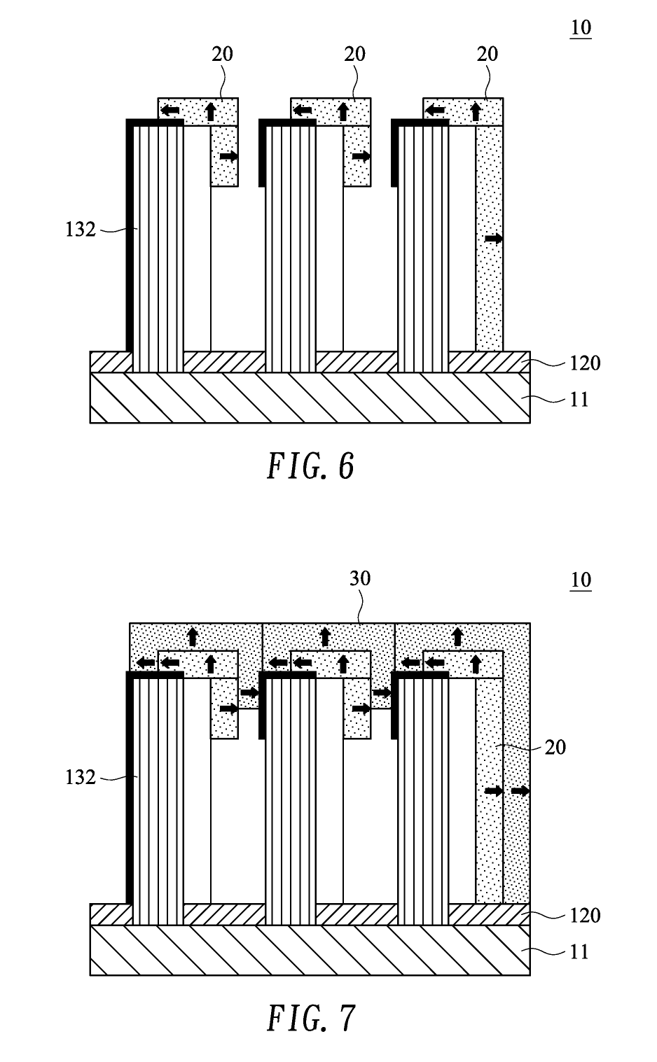

Forming a substrate (S30): Referring to FIG. 4, after the lateral crystal growth process is performed for the plurality of times, the widths of the extra-width nanorods 20 are incrementally increased to such extent that the incrementally widened extra-width nanorods 20 begin to bond with each other. Meanwhile, the top ends of the extra-width nanorods 20 are joined to form a film, i.e., the substrate 30. As the nanorods 130 in the present embodiment are made of gallium nitride, the substrate 30 thus formed is a gallium nitride substrate 30.

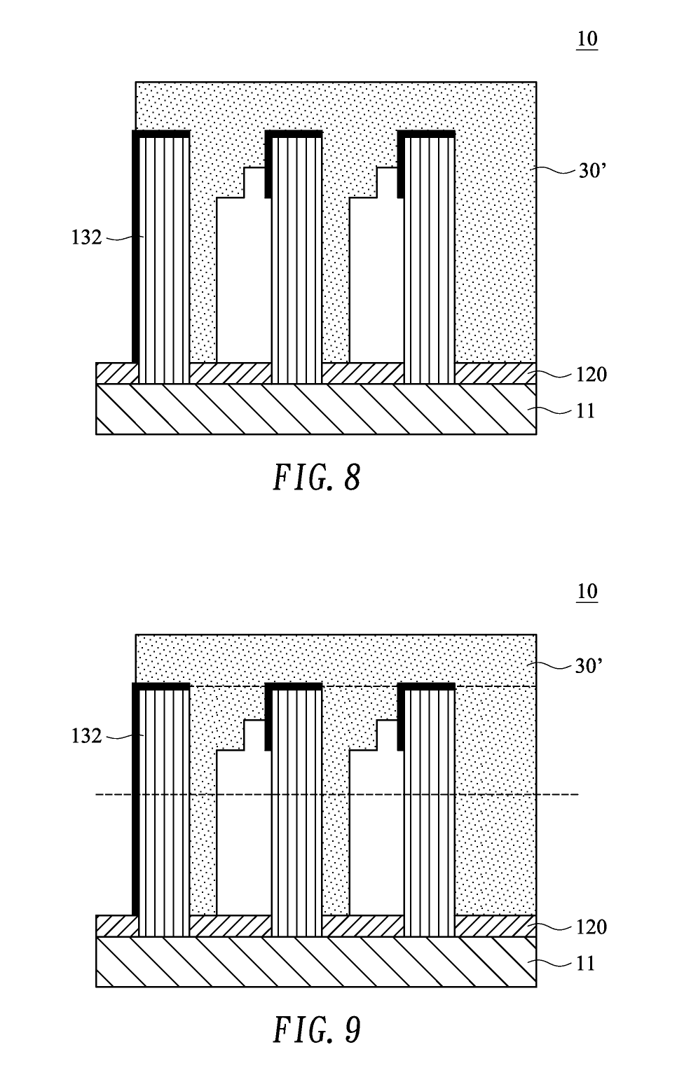

Forming a seed layer (S40): Referring to FIG. 5, after the gallium nitride substrate 30 is formed, an annealing process is performed at least on the gallium nitride substrate 30 so that the grain boundary and internal stress at the interface between each two adjacent extra-width nanorods 20 can be eliminated by high-temperature annealing in an atmosphere. The annealing step is intended to increase the otherwise weak molecular bond at the grain boundaries. Generally, the gas for use in the annealing process is a high-purity low-cost gas such as argon and hydrogen, and the gas serves to fill the defects in the gallium nitride substrate 30.

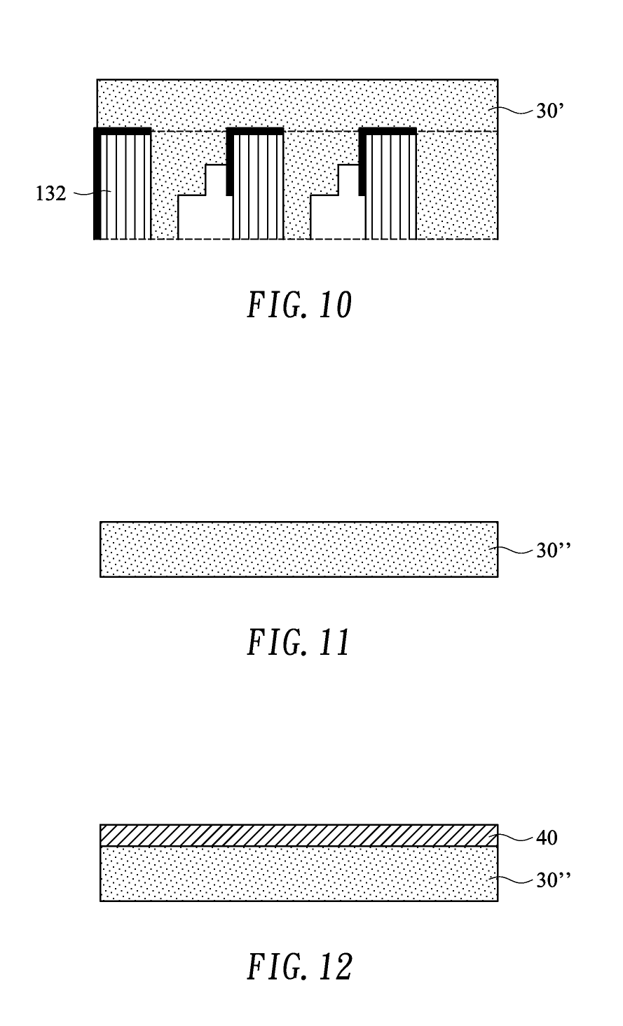

By the annealing step, the gallium nitride substrate 30 which has undergone multiple lateral crystal growths is turned into a seed layer 30′. As shown in FIG. 6, the seed layer 30′ has a flat and defect-free surface and is therefore suitable for use as a growth substrate on which a gallium nitride layer 40 can be grown by metal-organic chemical vapor deposition. Aside from the gallium nitride layer 40, the seed layer 30′ is suitable for growing other semiconductor layers as well. The seed layer 30′ formed in this embodiment can overcome the thickness limitation of the gallium nitride layer 40 so that the resultant gallium nitride layer 40 is thicker than in the prior art.

In this embodiment, the incremental-width nanorods 130 are formed on the base layer 10 by a technique that enables transverse growth and bonding of the nanorods 130. Furthermore, there are gaps between the bottom portions of each two adjacent nanorods 130. As the gaps can buffer the stresses generated during the manufacturing process, the nanorods 130 together with the gaps play the same role as the buffer layer in the prior art, i.e., to prevent the gallium nitride layer 40 from damage or cracks attributable to such stresses.

In addition, with the nanorods 130 being widened by lateral growth and having transversely distributed lattices, the incremental-width nanorods 130 can be easily severed along the transverse direction. Therefore, once the thickness of the gallium nitride layer 40 growing from the seed layer 30′ is increased, the gallium nitride layer 40 can be readily taken off by severing the nanorods 130, without causing damage to the gallium nitride layer 40. Thus, the yield rate of the manufacturing process can be raised.

The features of the present invention are disclosed above by the preferred embodiments to allow persons skilled in the art to gain insight into the contents of the present invention and implement the present invention accordingly. The preferred embodiments of the present invention should not be interpreted as restrictive of the scope of the present invention. Hence, all equivalent modifications or amendments made to the aforesaid embodiments should fall within the scope of the appended claims.

What is claimed is:

1. A method for making a flat substrate from incremental-width nanorods, comprising the steps of:
providing a base layer having a plurality of nanorods;
performing a lateral crystal growth process for a plurality of times to enable lateral crystal growth of the nanorods, wherein each time the lateral crystal growth process is performed, an additive reagent is added at a different concentration; and
forming a substrate, wherein after the lateral crystal growth process is performed for the plurality of times to widen the nanorods incrementally, the nanorods bond with each other to form the substrate.

2. The method of claim 1, wherein the base layer comprises a base board made of monocrystalline silicon, silicon carbide, sapphire, or lithium aluminate.

3. The method of claim 1, wherein the nanorods are distributed over the base layer in a spaced manner.

4. The method of claim 1, wherein the step of performing a lateral crystal growth process for a plurality of times is implemented by metal-organic chemical vapor deposition (MOCVD) so as to enable lateral crystal growth of the nanorods.

5. The method of claim 4, wherein the metal-organic chemical vapor deposition involves a trimethylgallium gas, an ammonia gas, and the additive reagent so as to enable lateral crystal growth of the nanorods.

6. The method of claim 5, wherein the additive reagent is a nitride-based compound or hydrogen.

7. The method of claim 1, wherein the additive reagent is a nitride-based compound or hydrogen.

8. The method of claim 1, wherein the nanorods are made of a semiconductor material.

9. The method of claim 8, wherein the nanorods are made of a III-V compound semiconductor or a II-VI compound semiconductor.

10. The method of claim 8, wherein the nanorods are made of gallium nitride.

11. The method of claim 1, further comprising the step of: forming a seed layer by annealing at least the substrate.
